(19) United States
(12) Patent Application Publication
(10) Pub. No.: US 2026/0076199 A1
(43) Pub. Date: Mar. 12, 2026

(54) WAFER BONDED TOP-SIDE COOLING MODULE WITH THERMAL INTERFACE MATERIAL CONTAINMENT

(71) Applicant: Qorvo US, Inc., Greensboro, NC (US)

(72) Inventors: MD Hasnine, Richardson, TX (US); Matthew Essar, Wylie, TX (US)

(21) Appl. No.: 19/288,431

(22) Filed: Aug. 1, 2025

Related U.S. Application Data
(60) Provisional application No. 63/693,418, filed on Sep. 11, 2024.

(51) Int. Cl. H01L 23/42; H01L 23/00; H01L 23/36; H01L 25/07

(52) U.S. Cl. CPC H10W 40/70; H10W 40/10; H10W 90/00; H10W 72/877; H10W 90/724; H10W 90/736

(57) ABSTRACT

The present disclosure relates to a microelectronics module featuring thermal interface material (TIM) containment for efficient and reliable top-side cooling, and a process for making the same. The microelectronics module includes a module substrate, a flip-chip die attached to the module substrate, and a heat spreader positioned above and thermally coupled to the flip-chip die. A TIM barrier, partially embedded in a mold compound, continuously surrounds the heat spreader and protrudes vertically beyond the heat spreader to define a TIM cavity over the heat spreader. A TIM section fills the TIM cavity to cover the heat spreader. A heat sink is in contact with both the TIM section and the TIM barrier, where the TIM barrier is configured to prevent the TIM section from shifting away from over the heat spreader, thereby maintaining thermal coupling between the heat sink and the heat spreader through the TIM section.

### RELATED APPLICATIONS

This application claims the benefit of provisional patent application Ser. No. 63/693,418, filed Sep. 11, 2024, the disclosure of which is hereby incorporated herein by reference in its entirety.

### FIELD OF THE DISCLOSURE

The present disclosure relates to a microelectronics module with thermal interface material containment to achieve top-side cooling, and a process for making the same.

### BACKGROUND

With faster switching speed, higher breakdown strength, and lower on-resistance, high-power radio frequency (RF) devices based on gallium nitride (GaN)/gallium arsenide (GaAs) technology significantly outperform silicon-based devices. To further enhance the breakdown voltage and maximum output power, it is desired to decrease gate spacing of GaN/GaAs devices. As the gate spacing of the GaN/GaAs devices decreases, there is an increase in concentrated heat flux in the die bodies. Effectively managing device heating and controlling junction temperatures becomes essential, given their potential to negatively impact performance and reliability. In the case of the high-power RF devices attached to a laminate substrate, the ability to dissipate large amounts of heat through the laminate substrate underneath the devices (bottom-side cooling) is limited. This limitation results in high thermal resistance, ultimately degrading the device's lifetime.

A wafer-to-wafer bonding process allows an additional heat sink on top of the device within a microelectronics module, which enables heat dissipation at the top side of the microelectronics module and provides flexibility to use a customized heat sink. However, thermal interface materials, which are used to connect the heat sink to the device and transfer heat from the device to the heat sink may be squeezed out or may shift away from the desired interface between the device and the heat sink during a thermal or power cycling. This displacement degrades thermal performance of the device and reduces the lifetime of the device.

Accordingly, there remains a need for improved module designs, which provide an integrated structural solution for the thermal interface material containment, so as to provide an efficient and reliable path for heat dissipation of the high-power/high frequency electronic components in the microelectronics module.

### SUMMARY

The present disclosure relates to a microelectronics module with thermal interface material (TIM) containment for efficient and reliable top-side cooling, and a process for making the same. The disclosed microelectronics module includes a module substrate, at least one flip-chip die, at least one heat spreader, a mold compound, at least one TIM section, at least one TIM barrier, and a heat sink. Herein, the at least one flip-chip die is attached to a top surface of the module substrate, and the at least one heat spreader resides over and is thermally coupled to the at least one flip-chip die. The mold compound is formed over the top surface of the module substrate and surrounds the at least one flip-chip die and the at least one heat spreader, and a top surface of the mold compound and a top surface of the at least one heat spreader are coplanar. The at least one TIM barrier, partially embedded in the mold compound, continuously surrounds a periphery of the at least one heat spreader and protrudes vertically beyond the top surface of the at least one heat spreader to provide at least one TIM cavity above the at least one heat spreader. The at least one TIM section covers at least the top surface of the at least one heat spreader and fills the at least one TIM cavity. The heat sink is in contact with both the at least one TIM section and the at least one TIM barrier, and the at least one TIM barrier is configured to prevent the at least one TIM section from shifting away from the top surface of the at least one heat spreader. As such, the heat sink resides over and is thermally coupled to the at least one heat spreader through the at least one TIM section.

In one embodiment of the microelectronics module, the at least one TIM section is formed of one of a thermal paste, a thermal gel, and a thermal grease, each of which has a thermal conductivity larger than 3 W/m.K.

In one embodiment of the microelectronics module, the at least one TIM barrier is formed of an adhesive material or an epoxy material.

In one embodiment of the microelectronics module, the at least one flip-chip die comprises gallium nitride (GaN), gallium arsenide (GaAs), or silicon.

In one embodiment of the microelectronics module, the at least one flip-chip die includes a die body, multiple die interconnects, and multiple die vias. The die interconnects extend outwardly from the die body and are coupled to the top surface of the module substrate through solder caps, respectively, and the die vias extend through the die body and are coupled to corresponding die interconnects, respectively.

According to one embodiment, the microelectronics module further includes an underfilling material, which at least encapsulates each of the solder caps.

In one embodiment of the microelectronics module, the at least one heat spreader is formed of silicon carbide.

In one embodiment of the microelectronics module, the at least one heat spreader is thermally connected to the at least one flip-chip die through a sintered layer that has a thermal conductivity larger than 60 W/m. K.

According to one embodiment, the microelectronics module further includes a number of contact structures formed on a bottom surface of the module substrate.

In one embodiment of the microelectronics module, the contact structures are configured as a Ball Grid Array (BGA).

In one embodiment of the microelectronics module, the contact structures are configured as a Land Grid Array (LGA).

In one embodiment of the microelectronics module, the module substrate is a laminate-based substrate.

According to one embodiment, a first alternative microelectronic module includes a module substrate, at least one flip-chip die, at least one heat spreader, a mold compound, a TIM section, and a heat sink. The at least one flip-chip die is attached to a top surface of the module substrate, and the at least one heat spreader resides over and is thermally coupled to the at least one flip-chip die. The mold compound is formed over the top surface of the module substrate and surrounds the at least one flip-chip die and the at least one heat spreader.

Herein, a top surface of the mold compound and a top surface of the at least one heat spreader are coplanar. A number of heat spreader notches are formed at the top surface of the at least one heat spreader. The TIM section fills each of the heat spreader notches and extends over the top surface of the at least one heat spreader and the top surface of the mold compound. The heat sink directly resides on the TIM section and is thermally coupled to the at least one heat spreader through the TIM section. The heat spreader notches are configured to constrain certain portions of the TIM section confined within the top surface of the at least one heat spreader.

In one embodiment of the first alternative microelectronics module, the heat spreader notches include one or more of discrete micro-holes, strip trenches, ring trenches, semi-ring trenches, and spiral trenches.

In one embodiment of the first alternative microelectronics module, a cross-sectional view of each of the heat spreader notches is triangular, semicircular, or square.

In one embodiment of the first alternative microelectronics module, at least one mold compound notch is formed at the top surface of the mold compound and surrounds the at least one heat spreader. The TIM section fills the at least one mold compound notch and each of the heat spreader notches and extends over the top surface of the at least one heat spreader and the top surface of the mold compound.

In one embodiment of the first alternative microelectronics module, the heat spreader notches include one or more of discrete micro-holes, strip trenches, ring trenches, semi-ring trenches, and spiral trenches. The at least one mold compound notch includes one or more of discrete micro-holes, strip trenches, ring trenches, semi-ring trenches, and spiral trenches.

In one embodiment of the first alternative microelectronics module, a cross-sectional view of each of the heat spreader notches is triangular, semicircular, or square. A cross-sectional view of the at least one mold compound notch is triangular, semicircular, or square.

According to one embodiment, a second alternative microelectronic module includes a module substrate, at least one flip-chip die, at least one heat spreader, a mold compound, a TIM section, and a heat sink. The at least one flip-chip die is attached to a top surface of the module substrate, and the at least one heat spreader resides over and is thermally coupled to the at least one flip-chip die. The mold compound is formed over the top surface of the module substrate and surrounds the at least one flip-chip die and the at least one heat spreader. Herein, a top surface of the mold compound and a top surface of the at least one heat spreader are coplanar. At least one mold compound notch is formed at the top surface of the mold compound and surrounds the at least one heat spreader. The TIM section fills the at least one mold compound notch and extends over the top surface of the at least one heat spreader and the top surface of the mold compound. The heat sink directly resides on the TIM section and is thermally coupled to the at least one heat spreader through the TIM section. The at least one mold compound notch is configured to constrain certain portions of the TIM section confined within the top surface of the at least one heat spreader.

According to one embodiment, a communication device includes a control system, a baseband processor, receive circuitry, and transmit circuitry. At least one or any combination of the control system, the baseband processer, the transmit circuitry, and the receive circuitry is implemented in a microelectronic module, which has a module substrate, at least one flip-chip die, at least one heat spreader, a mold compound, at least one TIM section, at least one TIM barrier, and a heat sink. Herein, the at least one flip-chip die is attached to a top surface of the module substrate, and the at least one heat spreader resides over and is thermally coupled to the at least one flip-chip die. The mold compound is formed over the top surface of the module substrate and surrounds the at least one flip-chip die and the at least one heat spreader, and a top surface of the mold compound and a top surface of the at least one heat spreader are coplanar. The at least one TIM barrier, partially embedded in the mold compound, continuously surrounds a periphery of the at least one heat spreader and protrudes vertically beyond the top surface of the at least one heat spreader to provide at least one TIM cavity over the at least one heat spreader. The at least one TIM section covers at least the top surface of the at least one heat spreader and fills the at least one TIM cavity. The heat sink is in contact with both the at least one TIM section and the at least one TIM barrier, and the at least one TIM barrier is configured to prevent the at least one TIM section from shifting away from the top surface of the at least one heat spreader. As such, the heat sink resides over and is thermally coupled to the at least one heat spreader through the at least one TIM section.

According to one embodiment, a method of fabricating a microelectronic module starts with providing a precursor module, which includes a module substrate, at least one flip-chip die, at least one heat spreader, and a mold compound. Herein, the at least one flip-chip die is attached to a top surface of the module substrate, and the at least one heat spreader resides over and is thermally coupled to the at least one flip-chip die. The mold compound is formed over the top surface of the module substrate and surrounds the at least one flip-chip die and the at least one heat spreader, and a top surface of the mold compound and a top surface of the at least one heat spreader are coplanar. Next, at least one ring trench is formed within the mold compound, which continuously surrounds the at least one heat spreader and extends vertically from the top surface of the mold compound and downwardly into the mold compound. An adhesive material is then applied to fill the at least one ring trench and protrude the top surface of the at least one heat spreader, so as to form at least one TIM barrier continuously surrounding the at least one heat spreader. The protrusion of the at least one TIM barrier provides at least one TIM cavity over the top surface of the at least one heat spreader. A TIM is applied over the top surface of the at least one heat spreader and fully fills the at least one TIM cavity to provide at least one TIM section. Lastly, a heat sink is placed in contact with the at least one TIM section and the at least one TIM barrier. The TIM barrier is configured to prevent the at least one TIM section from shifting away from the top surface of the at least one heat spreader, thereby maintaining thermal coupling between the heat sink and the at least one heat spreader through the TIM section.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIGS. 1A-1B illustrate an exemplary implementation of a microelectronics module with thermal interface material containment for efficient and reliable top-side cooling according to aspects of the present disclosure.

FIGS. 2A-2F illustrate an alternative implementation of the microelectronics module with thermal interface material containment according to aspects of the present disclosure.

FIGS. 3-4 illustrate other alternative implementations of the microelectronics module with thermal interface material containment according to aspects of the present disclosure.

FIGS. 5-15 illustrate steps of a process of fabricating the microelectronics module shown in FIG. 1A according to some embodiments of the present disclosure.

FIGS. 16-18 illustrate steps of an alternative process of fabricating the microelectronics module shown in FIG. 2A according to some embodiments of the present disclosure.

FIG. 19 illustrates a block diagram of a communication device, which may include the microelectronics module illustrated in FIGS. 1A and 2A according to some embodiments of the present disclosure.

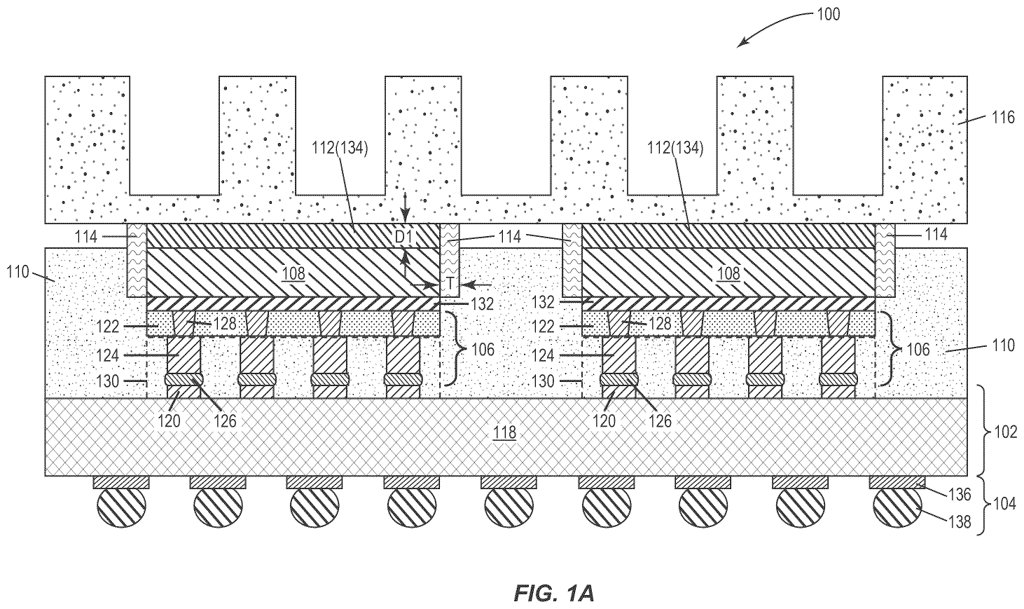

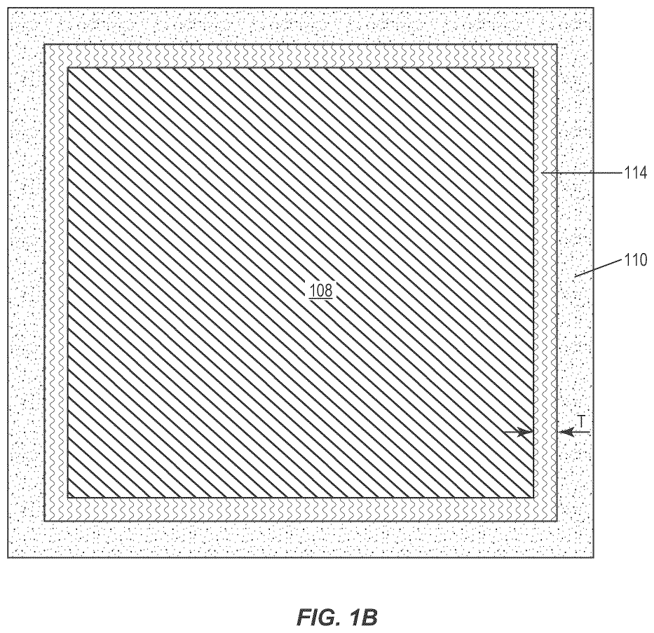

It will be understood that for clarity of illustration, FIGS. 1-19 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

For high-power radio frequency (RF) devices, such as gallium nitride (GaN)/gallium arsenide (GaAs) devices, bottom-side cooling through a package laminate substrate is limited, which may negatively impact electrical performance and device reliability. Top-side cooling for the high-power RF devices is imperative to establish an alternative/additional thermal pathway to an ambient environment. Compared to wire-bonding dies, flip-chip assembly technology, besides its preferable solder interconnection to the package substrate (which helps in reducing the die size, reducing the overall size of the package, shorting the electrical path to the package laminate substrate, and reducing undesired inductance and capacitance), also provides the capability for the top-side cooling. A backside (i.e., the tallest portion) of one flip chip die is typically inactive, which allows the backside of the flip chip die to be connected to a high thermally conductive component above, so as to provide an upward heat dissipation path.

In addition, a wafer-to-wafer bonding process allows an additional heat sink to be attached to the top side of the flip-chip die (via the high thermally conductive component) for further heat dissipation. In some applications, thermal interface materials (TIMs), such as thermal paste, thermal gel, or thermal grease, might be used for heat sink attachment. In order to ensure the desired thermal performance and lifetime of the final product, TIM containment is required, so that the TIM will not be squeezed out or will not shift away from the desired interface underneath the heat sink.

FIG. 1A illustrates a cross-sectional view of an exemplary microelectronics module 100 with TIM containment for efficient and reliable top-side cooling according to aspects of the present disclosure. For the purpose of this illustration, the microelectronics module 100 includes a module substrate 102, contact structures 104 (only one contact structure is labeled with a reference number for clarity), two flip-chip dies 106, two heat spreaders 108, a mold compound 110, two TIM sections 112, two TIM barriers 114 (a cross-sectional view of two TIM barriers 114), and a heat sink 116. The contact structures 104 are formed on a bottom surface of the module substrate 102, while the flip-chip dies 106 are attached to a top surface of the module substrate 102. The two heat spreaders 108 reside over and are thermally coupled to the two flip-chip dies 106, respectively. The mold compound 110 resides over the top surface of the module substrate 102 and surrounds the flip-chip dies 106 and the heat spreaders 108. Each TIM barrier 114 is partially embedded in the mold compound 110, surrounds a periphery of one corresponding heat spreader 108, and protrudes vertically beyond a top surface of the corresponding heat spreader 108, so as to retain a corresponding TIM section 112 over the respective heat spreader 108. The heat sink 116 resides over and is thermally coupled to each heat spreader 108 through a corresponding TIM section 112. In different applications, the microelectronics module 100 may include fewer or more flip-chip dies 106 with corresponding fewer or more heat spreaders 108, and corresponding fewer or more TIM barriers 114.

In detail, the module substrate 102 might be a laminate-base substrate, which is composed of organic materials and metal material used to form internal connections within the organic materials and/or electrical/thermal connections to external components (e.g., connection to the contact structures 104 and the flip-chip dies 106). In one embodiment, the module substrate 102 includes a substrate body 118 formed of one or more organic materials (e.g., FR4), multiple top substrate pads 120 (only two substrate pads are labeled with reference numbers for clarity) at a top surface of the substrate body 118, and internal metal structures (e.g., layers, traces, vias, etc. not shown) within the substrate body 118. The top substrate pads 120 may be formed of copper and are configured to accommodate the flip-chip dies 106.

Each flip-chip die 106 includes a die body 122 and multiple die interconnects 124 (only one die interconnect of each flip-chip die 106 is labeled with a reference number for clarity and simplicity) extending outwardly from a bottom surface of the die body 122 and towards the top surface of the module substrate 102. An active region (not shown) of each flip-chip die 106 is located at a bottom portion of the die body 122 and adjacent to the die interconnects 124. The die body 122 may be formed from GaN with silicon carbide (SiC), GaAs with SiC, silicon, or any appropriate semiconductor material(s). The die interconnects 124 may be copper pillars that are coupled to corresponding top substrate pads 120 via solder caps 126, respectively (only two solder caps are labeled with reference numbers for clarity and simplicity), at the top surface of the substrate body 118.

In some embodiments, each flip-chip die 106 includes multiple die vias 128 extending through the die body 122 and coupled to corresponding die interconnects 124, respectively (only one die via 128 of each flip-chip die 106 is labeled with a reference number for clarity). The die vias 128 are configured to dissipate heat generated in the die body 122 (e.g., heat generated in the active region of each flip-chip die 106) towards a backside of the flip-chip die 106, which enables top-side cooling of the flip-chip die 106, and towards the die interconnects 124 of the flip-chip die 106, which enables down-side cooling of the flip-chip die 106. Herein and hereafter, a backside surface of one flip-chip die 106 refers to a surface away from an active region of the flip-chip die 106 and opposite the die interconnects 124. In some cases, the backside of the flip-chip die 106 may be metalized (e.g., a plated metal film) as a grounding plane (not shown for simplicity). Note that since the majority of the module substrate 102 (i.e., the substrate body 118) is formed of organic materials, which do not have a high thermal conductivity, a combination of the die interconnects 124 and the module substrate 118 may not provide an efficient downward thermal path for the flip-chip dies 106.

In addition, each flip-chip die 106 may be underfilled by an underfilling material 130, such as an epoxy material, which encapsulates each solder cap 126 and its corresponding top substrate pad 120 and fills gaps between the bottom surface of the die body 122 and the top surface of the substrate body 118. The underfilling material 130 is configured to ensure the integrity of each solder cap 126 during a sintering process (more details are described below).

Each heat spreader 108 is attached to the backside of a corresponding flip-chip die 106 through a sintered layer 132. In one embodiment, each heat spreader 108 has a substantially same horizontal size as the corresponding flip-chip die 106. The heat spreaders 108 are formed of a material with a high thermal conductivity (a thermal conductivity larger than 300 W/m.K, e.g., between 330 W/m.K and 390 W/m.K), such as SiC, while the sintered layer 132 is formed of a sintering material with a high thermal conductivity (larger than 60 W/m.K, e.g., between 60 W/m.K and 75 W/m.K), such as sintering silver or sintering copper. Herein, the heat generated in each flip-chip die 106 (e.g., the heat generated by the active region of each flip-chip die 106 located at the bottom portion of the die body 122) can be efficiently dissipated upward through the die vias 128, the sintered layer 132, and a corresponding heat spreader 108.

The mold compound 110 is formed over the module substrate 102 and around the flip-chip dies 106 and the heat spreaders 108. The top surface of each heat spreader 108 is not covered by the mold compound 110 and is coplanar with a top surface of the mold compound 110. The mold compound 110 may be formed of an epoxy material.

Each TIM barrier 114 is a continuous barrier wall, which continuously surrounds the corresponding heat spreader 108 and protrudes vertically beyond the top surface of the corresponding heat spreader 108. As such a TIM cavity 134 is formed above the top surface of each heat spreader 108 and is surrounded by the corresponding TIM barrier 114 (i.e., the TIM barrier 114 defines a perimeter of the TIM cavity 134). The TIM cavity 134 may have a depth D1 between 40 μm and 80 μm. In one embodiment, each TIM barrier 114 extends vertically into the mold compound 110 and is in contact with a side surface of the corresponding heat spreader 108. FIG. 1B illustrates a top view of a horizontal layout of one heat spreader 108 and its corresponding TIM barrier 114. The TIM barriers 114 may be formed of an adhesive material or an epoxy material, with a thickness T between 40 μm and 120 μm. The TIM barrier 114 might be highly thermally conductive or lowly thermally conductive, but always provides a strong adhesion.

Each TIM section 112 is confined with a corresponding TIM cavity 134, surrounded by a corresponding TIM barrier 114, and in contact with the backside of a corresponding heat spreader 108. In some embodiments, each TIM section 112 fully covers the backside of the corresponding heat spreader 108 and is planarized with the corresponding TIM barrier 114 on top. Each TIM section 112 may be formed of a TIM, such as a thermal paste, a thermal gel, or a thermal grease, which is easily deformed and relocated, and has a relatively high thermal conductivity (a thermal conductivity larger than 3 W/m.K, e.g., between 3 W/m.K and 12 W/m.K).

The heat sink 116 is in contact with both the TIM sections 112 and the TIM barriers 114 function as dams that prevent the TIM sections 112 from being pumped out or displaced from the top surfaces of their respective heat spreaders 108. As such, the heat sink 116 can be reliably and efficiently thermally coupled to each heat spreader 108 through the corresponding TIM section 112.

Accordingly, the heat generated by the flip-chip dies 106 can be dissipated further upward from the heat spreaders 108 to the heat sink 18 through the TIM sections 112. In some embodiments, extra TIM sections may also exist directly between the top surface of the mold compound 110 and the heat sink 116 (not shown).

In this illustration, each contact structure 104 on the bottom surface of the module substrate 102 may include a bottom substrate pad 136 and a solder ball 138, such that contact structures 104 are implemented as a Ball Grid Array (BGA). In some cases, each contact structure 104 may simply be a metal pad (not shown), such that contact structures 104 are implemented as a Land Grid Array (LGA). Regardless of the implementation of the contact structures 104, the contact structures 104 are configured to connect the module substrate 102 to the next level of assembly (e.g., a printed circuit board).

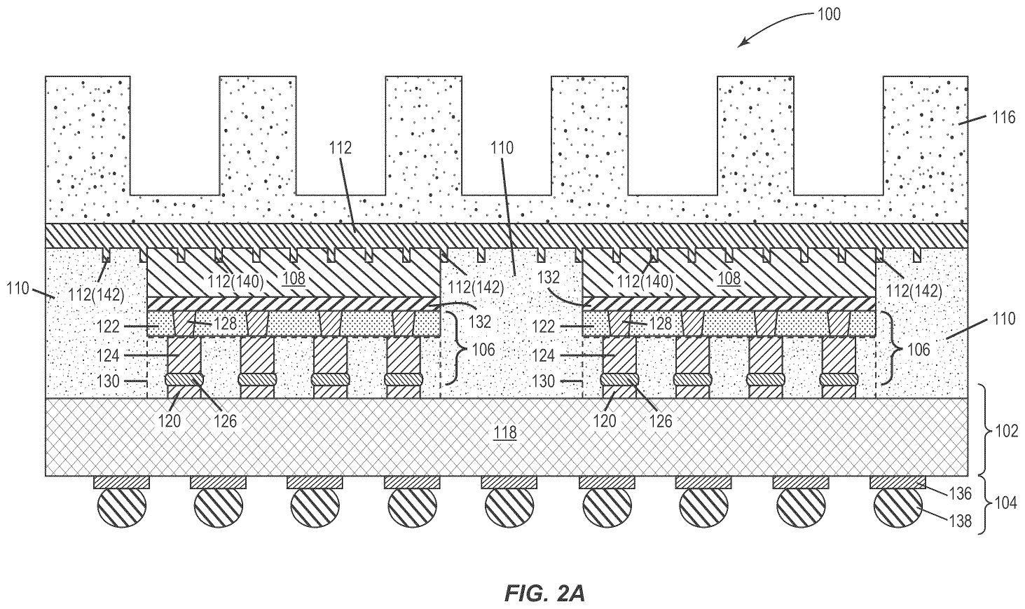

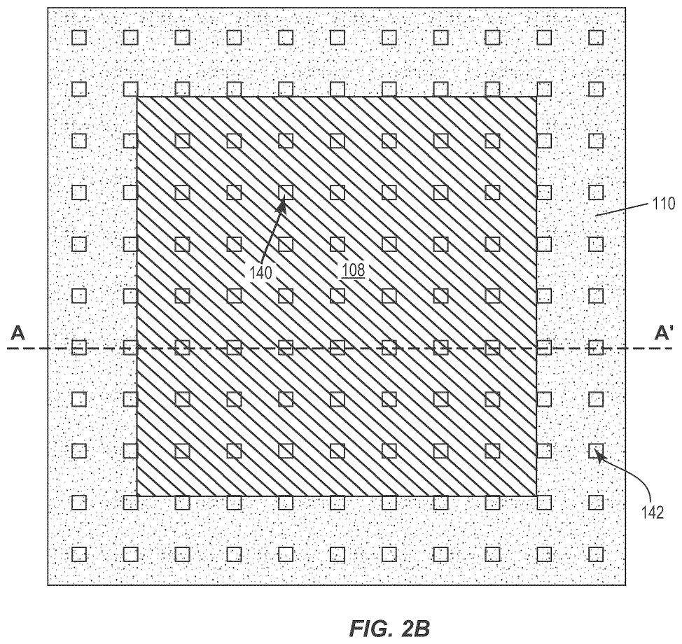

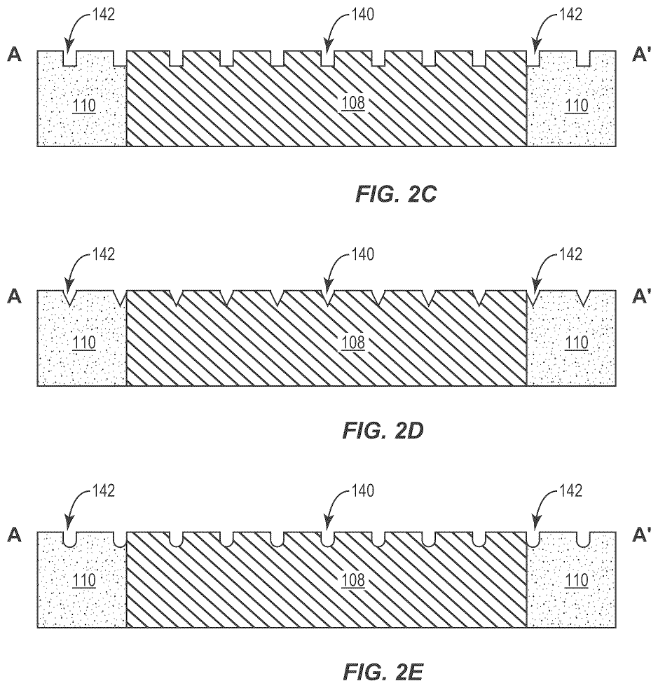

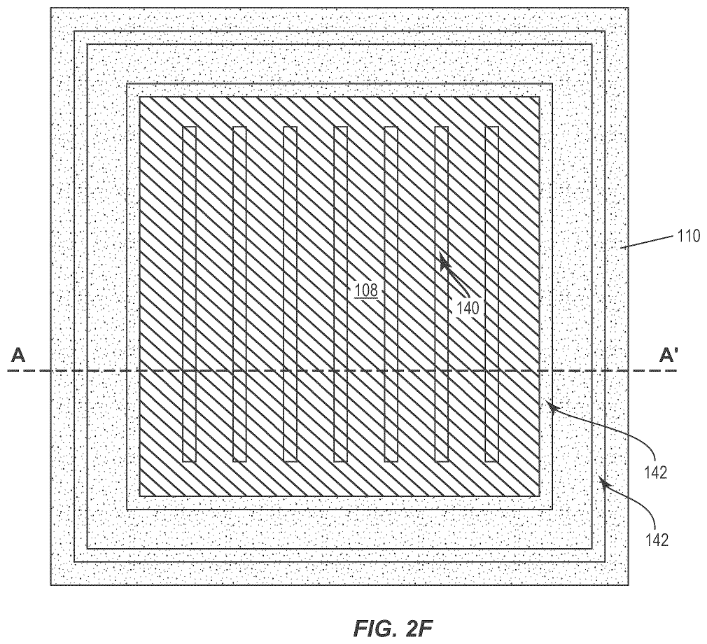

In some applications, the microelectronics module 100 may have an alternative solution for the TIM containment instead of the TIM barriers 114. As illustrated in FIG. 2A, the microelectronics module 100 still includes the module substrate 102, the contact structures 104 (e.g., BGA or LGA) formed on the bottom surface of the module substrate 102, the flip-chip dies 106 attached to the top surface of the module substrate 102, the heat spreaders 108 thermally coupled to the flip-chip dies 106 through the sintered layers 132, respectively, the mold compound 110 surrounding the flip-chip dies 106 and the heat spreaders 108, one TIM section 112, and the heat sink 116 residing over and thermally coupled to each heat spreader 108 through the TIM section 112. In this embodiment, instead of using the TIM barriers 114 to block the TIM section 112 to cover each heat spreader 108, the microelectronics module 100 may utilize notches within each heat spreader 108 (i.e., heat spreader notches 140, only two heat spreader notches are labeled with reference numbers for clarity) to retain excess TIM confined in each heat spreader 108, so as to avoid hotspot formation during a thermal or power cycling due to the TIM section 112 shifting/pumping-out and failed connection to the heat sink. In addition, the microelectronics module 100 may also utilize notches within the mold compound 110 and surrounding each heat spreader 108 (i.e., mold compound notches 142, only three mold compound notches 142 are labeled with reference numbers for clarity) as reservoirs to constrain the TIM section 112. Any TIM used to form the TIM section 112, if pumped out from the top surfaces of the heat spreaders 108, will be trapped in the mold compound notches 142 to prevent further pump-out.

Herein, each heat spreader notch 140 is formed at the top surface of a corresponding heat spreader 108 (i.e., each heat spreader notch 140 extends vertically from the top surface of the corresponding heat spreader 108 and downwardly into the corresponding heat spreader 108 without extending through the corresponding heat spreader 108). The mold compound notches 142 are formed at the top surface of the mold compound 110 and surround corresponding heat spreaders 108, respectively (i.e., each mold compound notch 142 extends vertically from the top surface of the mold compound 110 and downwardly into the mold compound 110 without extending vertically beyond the bottom surface of the corresponding heat spreader 108).

FIG. 2B illustrates a top view of a horizontal layout of the heat spreader notches 140 within one heat spreader 108 and the mold compound notches 142 that surround such heat spreader 108. In this illustration, the heat spreader notches 140 and the mold compound notches 142 are multiple discrete micro-holes, each of which may be formed in a variety of geometrical shapes. FIGS. 2C-2E illustrate non-limiting examples, where each of the heat spreader notches 140 and the mold compound notches 142 may be triangular, semicircular, or square when viewed from a side (e.g., along an A-A′ dashed line). The heat spreader notches 140 and the mold compound notches 142 might be formed with the same geometry or different geometries.

The number and location of the heat spreader notches 140 at the top surface of one heat spreader 108 may correspond to the number and horizontal arrangement of the die vias 128 of the corresponding flip-chip die 106. In some embodiments, the number of the heat spreader notches 140 within one heat spreader 108 is not less than the number of the die vias 128 within the corresponding flip-chip die 106, and the heat spreader notches 140 are located at least in alignment with the die vias 128 within the corresponding flip-chip die 106. In a non-limiting example, the heat spreader notches 140 within one heat spreader 108 are not only located in alignment with the die vias 128 within the corresponding flip-chip die 106, but also located horizontally between two adjacent die vias 128. Furthermore, in some embodiments, some of the mold compound notches 142 might be directly adjacent to the heat spreaders 108, while some of the mold compound notches 142 might be surrounding the heat spreaders 108 without directly contacting the heat spreaders 108. The heat spreader notches 140 and the mold compound notches 142 might be distributed in the horizontal plane at the same density or at different densities. In addition, the heat spreader notches 140 and the mold compound notches 142 might be distributed in the horizontal plane evenly or unevenly.

In some applications, the heat spreader notches 140 and the mold compound notches 142 may be continuous trenches, as illustrated in FIG. 2F (a top view of a horizontal layout of the heat spreader notches 140 within one heat spreader 108 and the mold compound notches 142 that surround such heat spreader 108). In this illustration, the heat spreader notches 140 within one heat spreader 108 include seven strip trenches, each of which is still formed at the top surface of the corresponding heat spreader 108 (i.e., each heat spreader notch 140 extends vertically from the top surface of the corresponding heat spreader 108 and downwardly into the corresponding heat spreader 108 without extending through the corresponding heat spreader 108). The mold compound notches 142 around the corresponding heat spreader 108 include two ring trenches, each of which is formed at the top surface of the mold compound 110 and surrounds the corresponding heat spreader 108 (i.e., each mold compound notch 142 extends vertically from the top surface of the mold compound 110 and downwardly into the mold compound 110 without extending vertically beyond the bottom surface of the corresponding heat spreader 108). A cross-sectional view of each of the strip trenches and the ring trench along the A-A′ dashed line (i.e., the cross-sectional view of each of the heat spreader notch 140 and the heat spreader notches 140) may be triangular, semicircular, or square, also as shown in FIGS. 2C-2E. In different applications, there might be fewer or more strip spreader trenches 140 within one heat spreader 108, and fewer or more ring mold compound trenches 142 around one heat spreader 108 (herein and hereafter, “heat spreader notches,” “strip spreader trenches,” and “ring/strip spreader trenches” are interchangeable, while “mold compound notches” and “ring mold compound trenches” are interchangeable). The heat spreader notches 140 and the mold compound notches 142 may be one or more shapes of trenches (e.g., strip trenches, ring trenches, semi-ring trenches, spiral trenches, etc.).

The number and location of the ring/strip spreader trenches 140 may still correspond to the number and horizontal arrangement of the die vias 128 of the corresponding flip-chip die 106. In a non-limiting example, the strip spreader trenches 140 within one heat spreader 108 extend over locations of all die vias 128 within the corresponding flip-chip die 106 as well as over locations horizontally between two adjacent die vias 128. Furthermore, in some embodiments, one of the ring mold compound trenches 142 might be directly adjacent to the heat spreaders 108, while the remaining ring mold compound trench(es) 142 might be surrounding the heat spreaders 108 without directly contacting the heat spreaders 108. In addition, the strip spreader trenches 140 and the ring mold compound trenches 142 might be distributed in the horizontal plane evenly or unevenly.

Returning to FIG. 2A, the TIM section 112 fills each of the heat spreader notches 140 and the mold compound notches 142 and extends over the top surface of each heat spreader 108 and the top surface of the mold compound 110. The heat sink 116 directly resides over the TIM section 112 so as to be thermally coupled to each heat spreader 108. The heat spreader notches 140 and the mold compound notches 142 help keep the TIM section 112 retained over the heat spreaders 108, such that the heat sink 116 can be reliably and efficiently thermally coupled to each heat spreader 108 through the TIM section 112. Accordingly, the heat generated by the flip-chip dies 106 can be dissipated further upward from the heat spreaders 108 to the heat sink 18 through the TIM section 112.

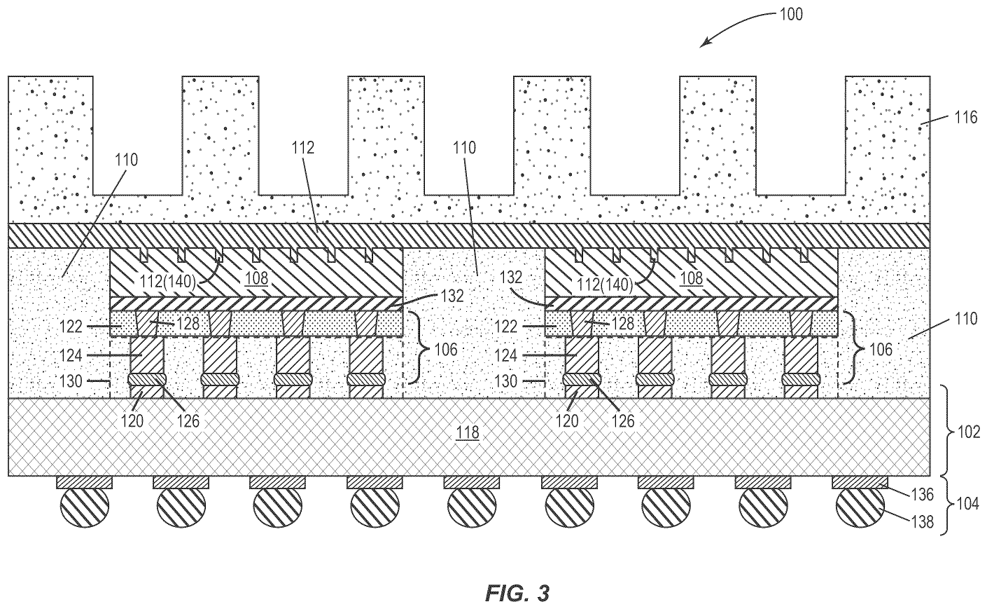

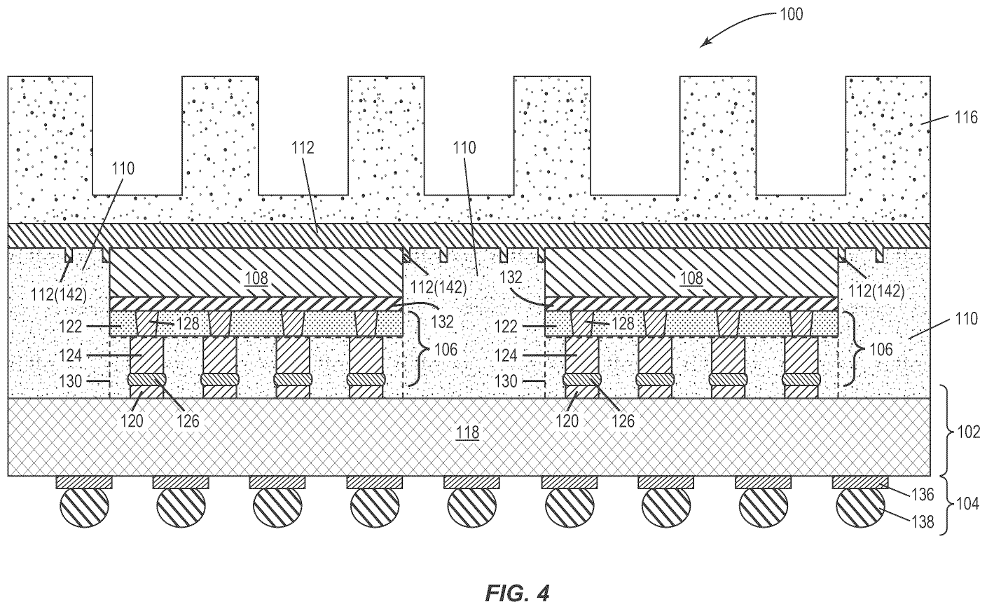

In different applications, the heat spreader notches 140 and the mold compound notches 142 may not be present at the same time. In some applications, there might be only the heat spreader notches 140 (e.g., discrete micro-holes and/or trenches) formed at the top surface of each heat spreader 108, as illustrated in FIG. 3. In some applications, there might be only the mold compound notches 142 (e.g., discrete micro-holes and/or trenches) formed at the top surface of the mold compound 110 and surrounding each heat spreader 108, as illustrated in FIG. 4.

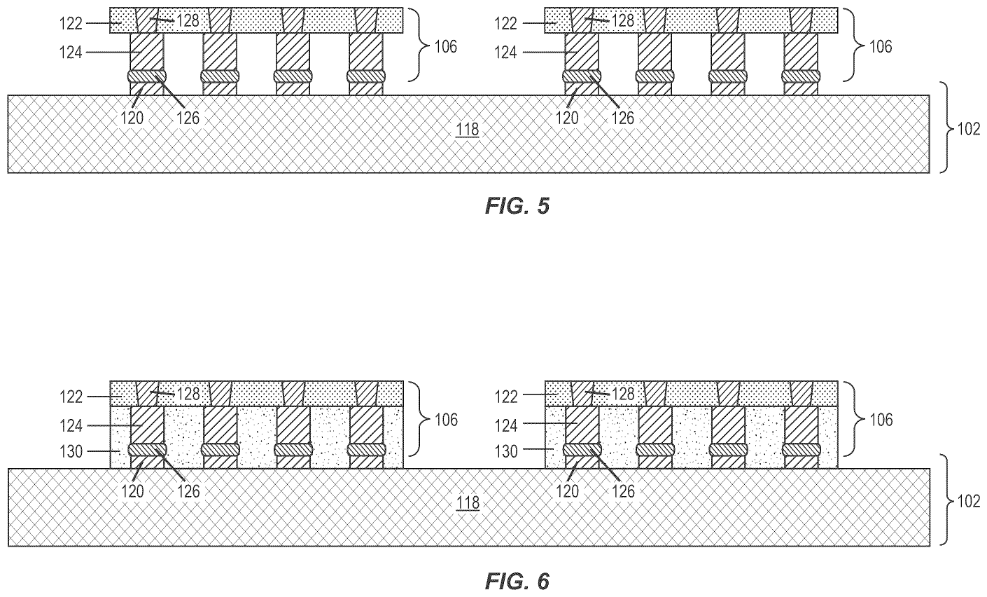

FIGS. 5-15 provide a process that illustrates exemplary steps to fabricate the microelectronics module 100 shown in FIG. 1A according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 5-15.

One or more flip-chip dies 106 are firstly attached to the top surface of the module substrate 102, as illustrated in FIG. 5. The module substrate 102 might be a laminate-base substrate, which includes the substrate body 118 formed of one or more organic materials (e.g., FR4), the top substrate pads 120 (only two substrate pads are labeled with reference numbers for clarity) at the top surface of the substrate body 118, and internal metal structures (e.g., layers, traces, vias, etc. not shown) within the substrate body 118. Each flip-chip die 106 may be a high-power RF die formed from GaN with SiC, GaAs with SiC, etc., or a relatively low-power die formed from silicon, and includes the die body 122 and the die interconnects 124 extending outwardly from the bottom surface of the die body 122 and coupled to the top substrate pads 120 at the top surface of the substrate body 118, respectively. Each die interconnect 124 might be coupled to a corresponding top substrate pad 120 via one solder cap 126. The active region (not shown) of each flip-chip die 106 is located at the bottom portion of the die body 122 and adjacent to the die interconnects 124. Herein, each die interconnect 124 is primarily configured to transmit electrical signals from the active region of each flip-chip die 106 to the module substrate 120. In some embodiments, each flip-chip die 106 may also include the die vias 128 that extend through the die body 122 and are coupled to the corresponding die interconnects 124, respectively. As such, the heat generated in the die body 122 of each flip-chip die 106 can be efficiently dissipated to the backside of the flip-chip die 124 through the die vias 128. In some cases, the backside of each flip-chip die 106 may be metalized (e.g., a plated metal film) as a grounding plane (not shown for simplicity).

Next, each flip-chip die 106 is underfilled by the underfilling material 130, as illustrated in FIG. 6. The underfilling material 130 encapsulates each solder cap 126 and its corresponding top substrate pad 120 and fills gaps between the bottom surface of the die body 122 and the top surface of the substrate body 118. A curing step may be followed to harden the underfilling material 126 (not shown).

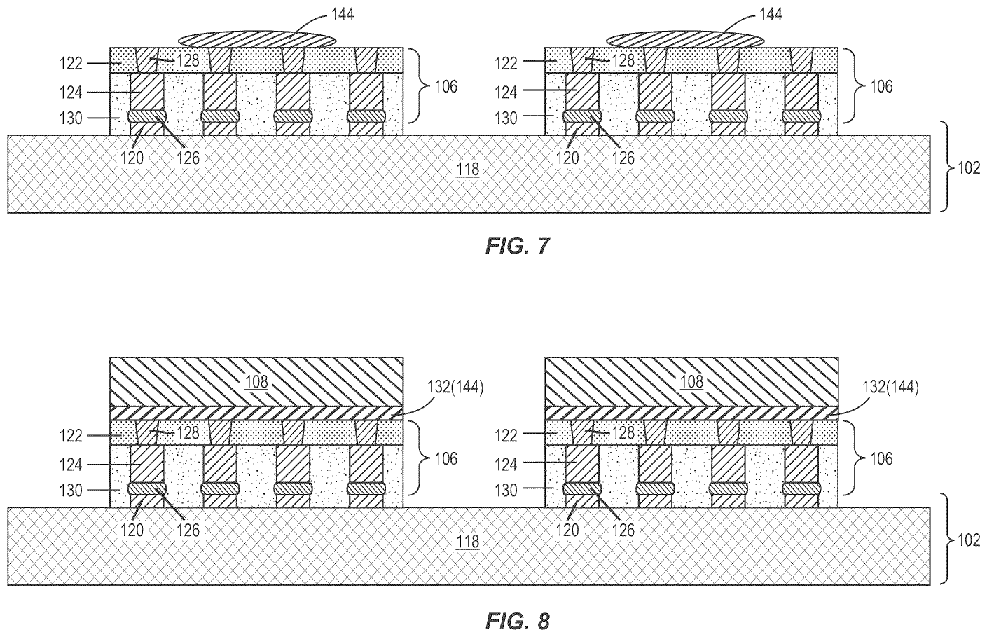

A sintering material 144, which has a high thermal conductivity (larger than 60 W/m.K, e.g., between 60 W/m.K and 75 W/m.K), such as sintering silver or sintering copper, is then applied to the backside of each flip-chip die 106, as illustrated in FIG. 7. The sintering material 144 may be applied by a dispensing process. After the sintering material 144 is applied, the heat spreaders 108 are placed over the flip-chip dies 106, respectively, as illustrated in FIG. 8. Herein, each heat spreader 108 is thermally coupled to the backside of a corresponding flip-chip die 106 through the sintering material 144. Following the placement of the heat spreaders 108, the sintering material 144 is cured (not shown). The sintering material 144 between each heat spreader 108 and the backside of the corresponding flip-chip die 106 is converted to the sintered layer 132. During the curing/sintering process, the underfilling material 130 ensures the integrity of each solder cap 126. Without the protection of the underfilling material 130, the solder caps 126 may be deformed or crack and cause electronic failure of the flip-chip dies 106.

The heat generated in the die body 122 of each flip-chip die 106 can be dissipated upward through the die vias 128, the sintered layer 132, and the corresponding heat spreader 108. Note that since the majority of the module substrate 102 (i.e., the substrate body 118) is formed of organic materials, which do not have a high thermal conductivity, the combination of the die interconnects 124 and the module substrate 118 may not provide an efficient downward thermal path for the flip-chip dies 106.

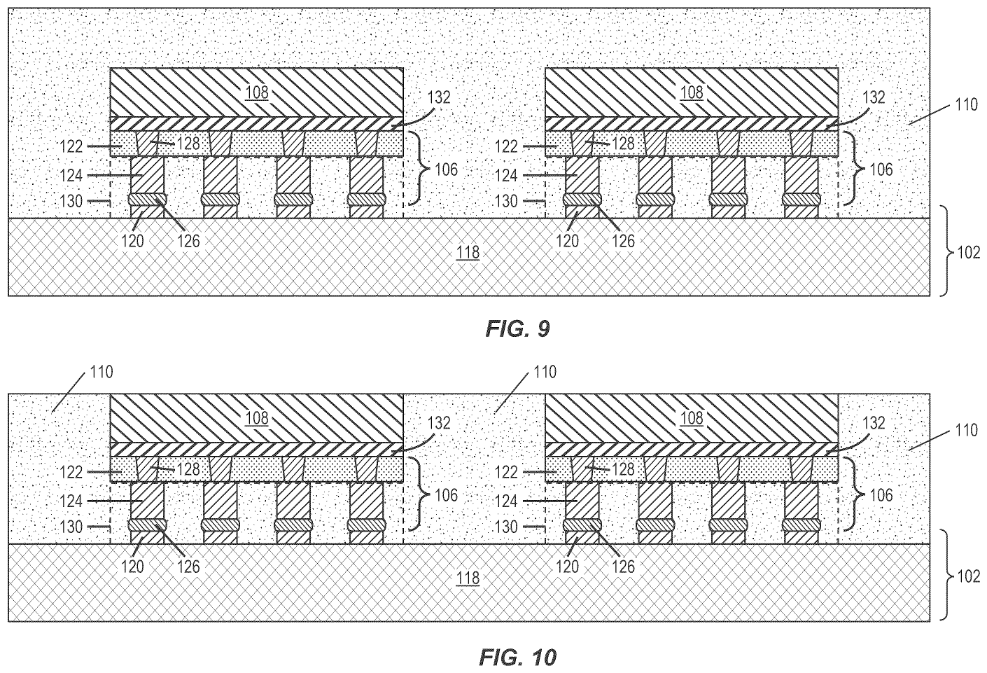

Next, the mold compound 110 is applied over the top surface of the module substrate 102 to encapsulate each flip-chip die 106 and its corresponding heat spreader 108, as illustrated in FIG. 9. The mold compound 110 may be applied by a compression molding, or the like. In some applications, the underfilling material 130 and the mold compound 110 may be formed from a same material, such as epoxy. During this molding step, the underfilling material 130 may also provide structural/mechanical support to the flip-chip dies 106, so as to mitigate deformation risk of the flip-chip dies 106. A curing step may be followed to harden the mold compound 110 (not shown). The mold compound 110 is then thinned down to expose the top surface of each heat spreader 108, as illustrated in FIG. 10. The thinning procedure may be done with a mechanical grinding process. After the thinning procedure, the top surface of each heat spreader 108 and the top surface of the mold compound 110 are coplanar.

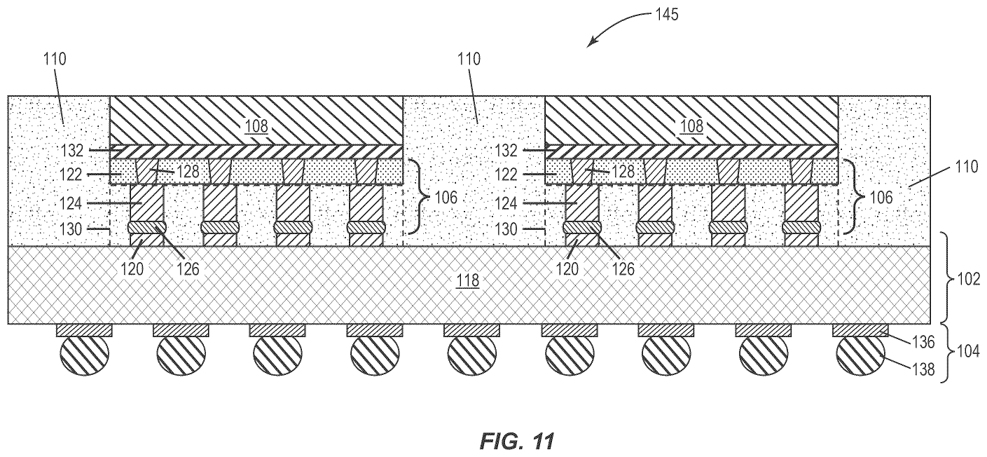

In some embodiments, the BGA technology might be used to form the contact structures 104 for the attachment to the next level of assembly. As shown in FIG. 11, the contact structures 104, each of which includes one bottom substrate pad 136 and one solder ball 138, are formed at the bottom surface of the module substrate 102 to provide a precursor module 145. Each contact structure 104 is connected to the metal structures within the substrate body 118 (not shown). In some embodiments, the LGA technology might be used for further attachment to the next level of assembly. Each contact structure 104 may simply be a metal pad formed at the bottom surface of the module substrate 102 and connected to the metal structures within the substrate body 118 (not shown).

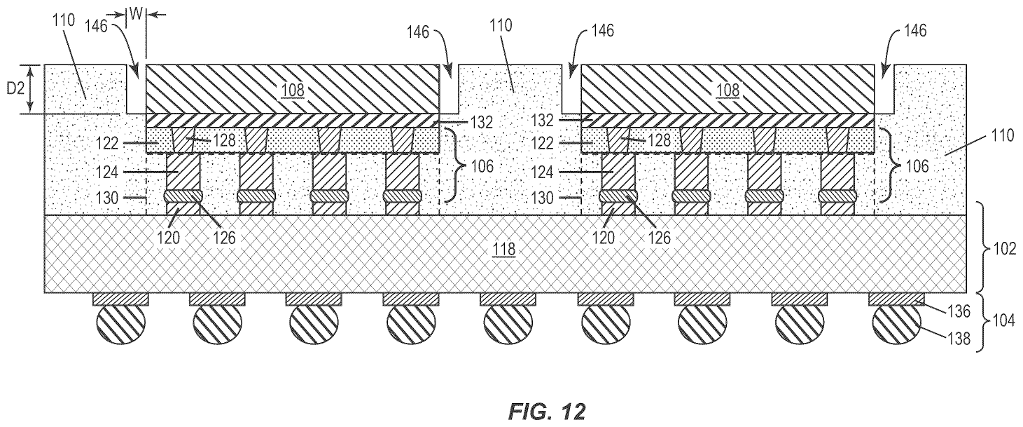

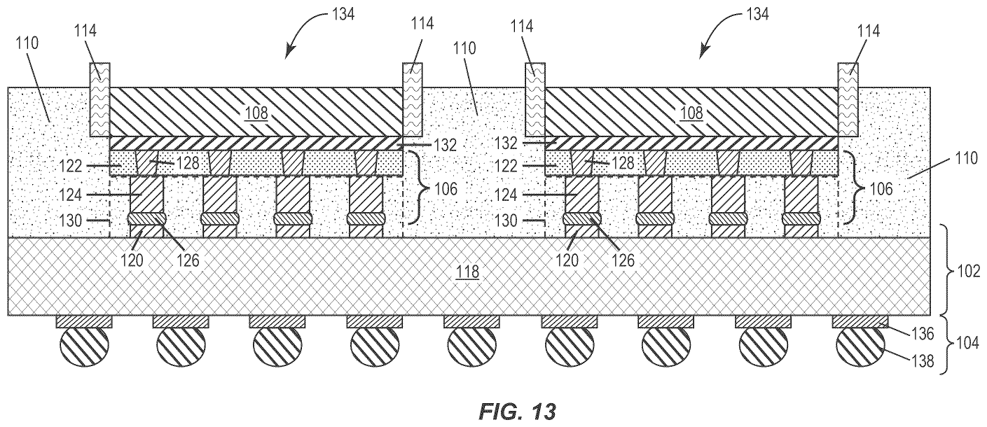

As shown in FIG. 12, ring trenches 146 are then formed within the mold compound 110 and surround each of the heat spreaders 108, respectively. Each ring trench 146 has the same horizontal layout as a corresponding TIM barrier 114 as illustrated in FIG. 1B and is similar to the horizontal layout of one mold compound notch 142 as illustrated in FIG. 2F. Each ring trench 146 extends vertically from the top surface of the mold compound 110 and downwardly into the mold compound 110 with a depth D2 between 80 μm and 160 μm, and a width W between 40μm and 120 μm (the same value as the thickness T of the TIM barriers 114). The ring trenches 146 might be etched by a laser ablation process. Once the ring trenches 146 are prepared, an adhesive material or an epoxy material is applied to fill each ring trench 146 and protrude through the top surface of the mold compound 110 and the top surface of each heat spreader 108 to form the TIM barriers 114, as illustrated in FIG. 13. The protrusions of each TIM barrier 114 over the top surface of the mold compound 110 provide the TIM cavity 134 over the corresponding heat spreader 108.

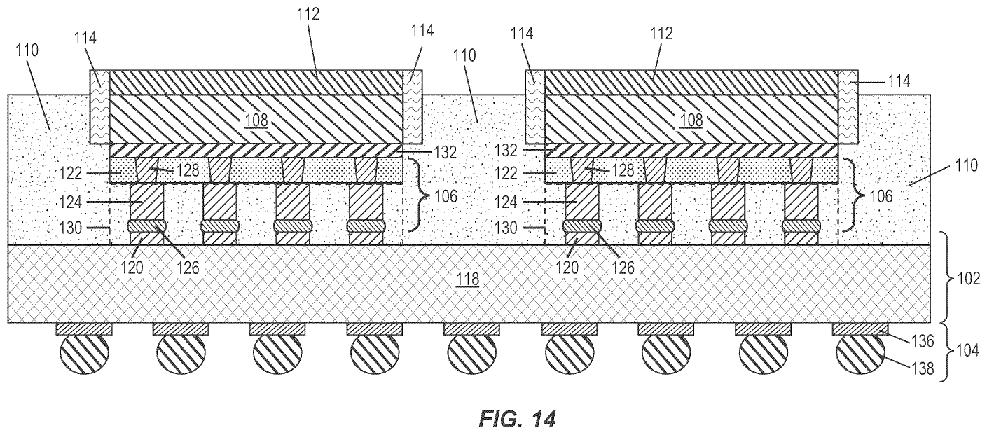

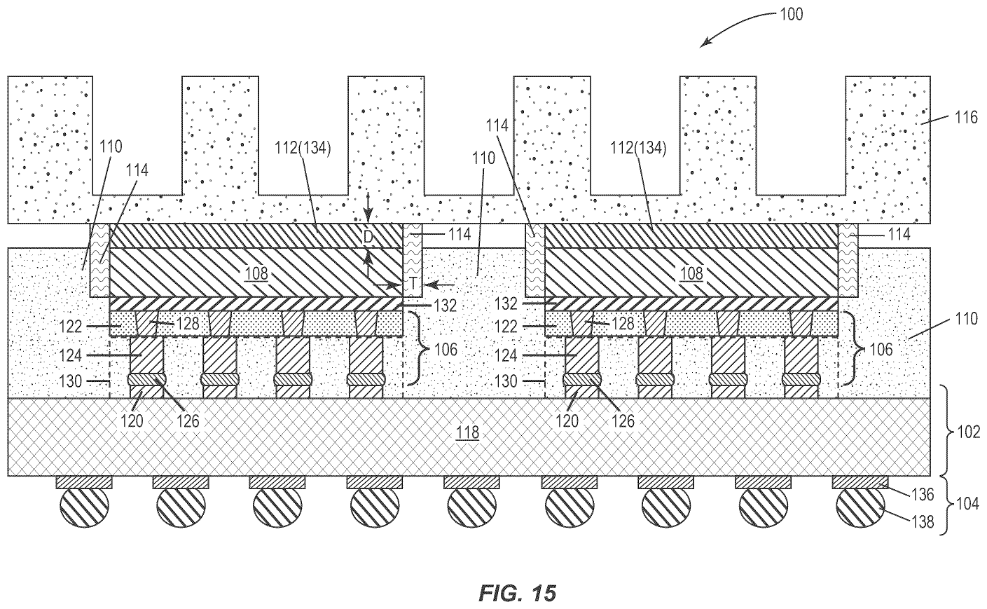

Next, a TIM is applied over the top surface of each heat spreader 108 and fully fills the corresponding TIM cavity 134 to form a respective TIM section 112, as illustrated in FIG. 14. In some applications, the TIM may also be applied directly over the top surface of the mold compound 110 outside of the TIM cavities 134 (not shown). The TIM used to form the TIM sections 112 may be thermal paste, thermal gel, or thermal grease. Lastly, the heat sink 116 is placed in contact with the TIM sections 112 and the TIM barriers 114 to complete the microelectronics module 100, as illustrated in FIG. 15. Herein, the TIM barriers 114 are configured to provide strong adhesion between the mold compound 110 and the heat sink 116, such that each TIM section 112 is encapsulated directly between one respective heat spreader 108 and the heat sink 116. During a thermal or power cycling of the microelectronics module 100, the TIM barriers 114 will function as dams for the respective TIM sections 112 to prevent TIM pump-out. Even if the TIM sections 112 are formed from a compressive film, the TIM barriers 114 can still prevent TIM pump-out under compressive force from the attachment of the heat sink 116.

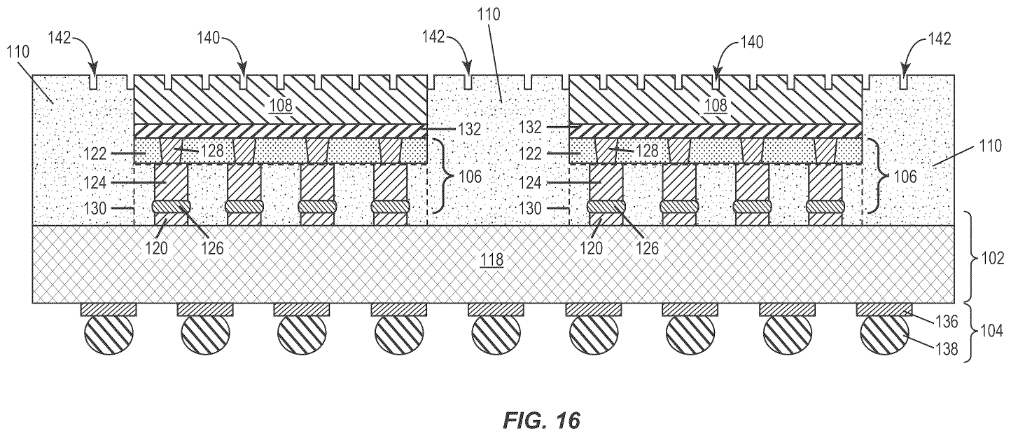

FIGS. 16-18 provide an alternative process of fabricating the microelectronics module 100 shown in FIG. 2A according to some embodiments of the present disclosure. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 16-18.

After the precursor module 145 is provided (as shown in FIG. 11), the heat spreader notches 140 and/or the mold compound notches 142 are formed, as shown in FIG. 16. Each heat spreader notch 140 is formed at the top surface of the corresponding heat spreader 108 and extends vertically from the top surface of the corresponding heat spreader 108 and downwardly into the corresponding heat spreader 108 without extending through the corresponding heat spreader 108. The mold compound notches 142 are formed at the top surface of the mold compound 110 and surround corresponding heat spreaders 108, respectively. Each mold compound notch 142 extends vertically from the top surface of the mold compound 110 and downwardly into the mold compound 110 without extending vertically beyond the bottom surface of the corresponding heat spreader 108. Each heat spreader notch 140 may be a discrete micro-hole or a trench with different cross-sectional geometries. Similarly, each mold compound notch 142 may be a discrete micro-hole or a trench with different cross-sectional geometries. The heat spreader notches 140 and/or the mold compound notches 142 might be formed by a laser ablation process.

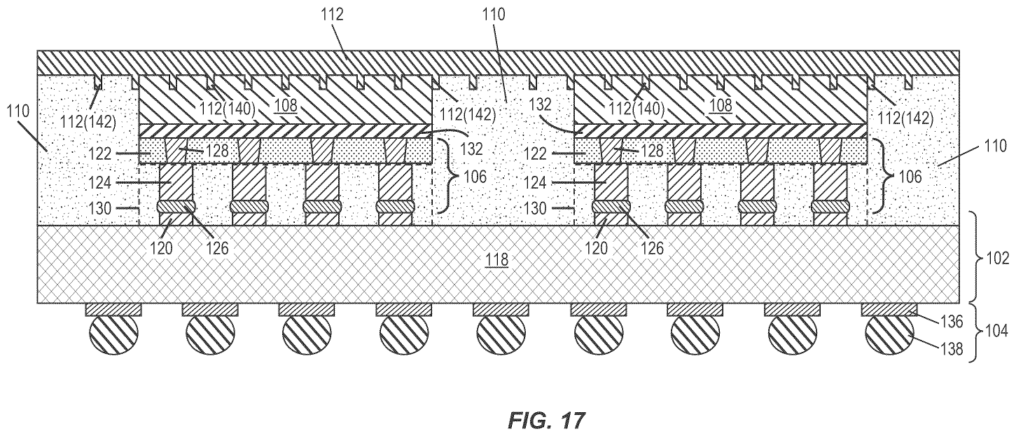

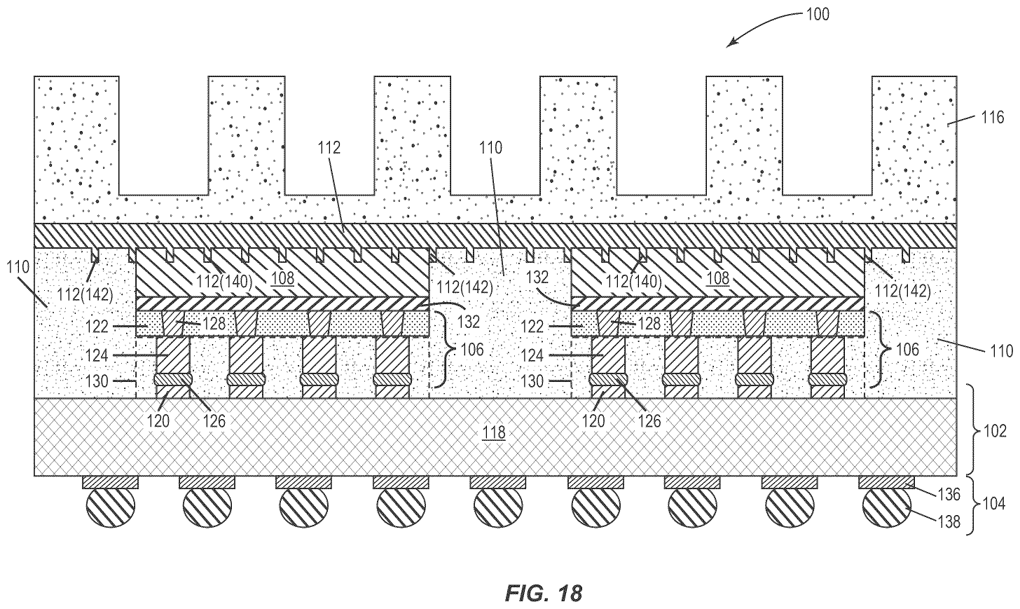

A TIM is then applied over the top surface of each heat spreader 108 and the top surface of the mold compound 110, fully filling each heat spreader notch 140 and each mold compound notch 142 to form the TIM section 112, as illustrated in FIG. 17. Lastly, the heat sink 116 is placed in contact with the TIM section 112 to complete the microelectronics module 100, as illustrated in FIG. 18. Herein, during the thermal or power cycling of the microelectronics module 100, even if TIM pump-out occurs, the heat spreader notches 140 are configured to retain some portion of the TIM section 112 in each heat spreader 108, and the mold compound notches 142 are configured to trap any portion of the TIM section 112 that is pumped out from the periphery of the corresponding heat spreader 108. As such, the heat sink 116 is always thermally coupled to the heat spreaders 108/the flip-chip dies 106 through the TIM section 112, and hotspot formation within the microelectronics module 100 can be avoided.

The systems and methods for reliable top-side heat dissipation of a microelectronic module, according to aspects disclosed herein, may be provided in or integrated into any high-power processor-based electronics. Examples, without limitation, include a base station, a military application device, a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

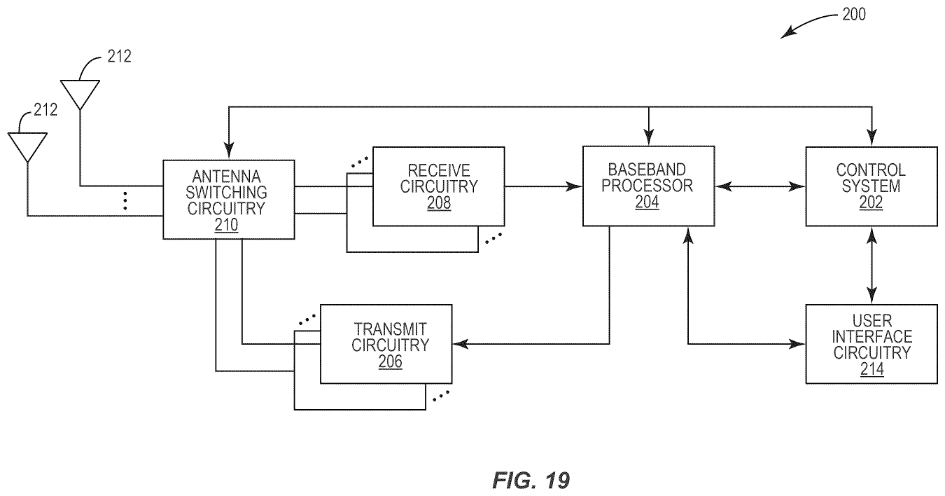

With reference to FIG. 19, the concepts described above may be implemented in various types of communication devices 200, such as those listed in the previous paragraph. The communication device 200 will generally include a control system 202, a baseband processor 204, transmit circuitry 206, receive circuitry 208, antenna switching circuitry 210, multiple antennas 212, and user interface circuitry 214. Herein, at least one or any combination of the control system 202, the baseband processor 204, the transmit circuitry 206, and the receive circuitry 208 may be implemented in the microelectronics module 100 (e.g. implemented in one or more of the flip-chip dies 106) described above.

In a non-limiting example, the control system 202 can be a field-programmable gate array (FPGA) or an application-specific integrated circuit (ASIC), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter of the receive circuitry 208 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and ASICs.

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A microelectronic module comprising:
a module substrate;
at least one flip-chip die attached to a top surface of the module substrate;
at least one heat spreader residing over and thermally coupled to the at least one flip-chip die;
a mold compound formed over the top surface of the module substrate and surrounding the at least one flip-chip die and the at least one heat spreader, wherein a top surface of the mold compound and a top surface of the at least one heat spreader are coplanar;
at least one thermal interface material (TIM) barrier that continuously surrounds a periphery of the at least one heat spreader and protrudes vertically beyond the top surface of the at least one heat spreader to provide at least one TIM cavity;
at least one TIM section covering at least the top surface of the at least one heat spreader and filling the at least one TIM cavity; and
a heat sink residing over and thermally coupled to the at least one heat spreader through the at least one TIM section, wherein the heat sink is in contact with both the at least one TIM section and the at least one TIM barrier, and the at least one TIM barrier is configured to prevent the at least one TIM section from shifting away from the top surface of the at least one heat spreader.

2. The microelectronic module of claim 1, wherein the at least one TIM section is formed of one of a thermal paste, a thermal gel, and a thermal grease, each of which has a thermal conductivity larger than 3 W/m.K.

3. The microelectronic module of claim 1, wherein the at least one TIM barrier is formed of an adhesive material or an epoxy material.

4. The microelectronic module of claim 1, wherein the at least one flip-chip die comprises gallium nitride (GaN), gallium arsenide (GaAs), or silicon.

5. The microelectronic module of claim 1, wherein the at least one flip-chip die includes a die body, multiple die interconnects extending outwardly from the die body and coupled to the top surface of the module substrate through solder caps, respectively, and multiple die vias extending through the die body and coupled to corresponding die interconnects, respectively.

6. The microelectronic module of claim 5 further comprises an underfilling material, which at least encapsulates each of the solder caps.

7. The microelectronic module of claim 1, wherein the at least one heat spreader is formed of silicon carbide.

8. The microelectronic module of claim 1, wherein the at least one heat spreader is thermally connected to the at least one flip-chip die through a sintered layer that has a thermal conductivity larger than 60 W/m.K.

9. The microelectronic module of claim 1 further comprises a plurality of contact structures formed on a bottom surface of the module substrate.

10. The microelectronic module of claim 9, wherein the plurality of contact structures is configured as a Ball Grid Array (BGA).

11. The microelectronic module of claim 9, wherein the plurality of contact structures is configured as a Land Grid Array (LGA).

12. The microelectronic module of claim 9, wherein the module substrate is a laminate-based substrate.

13. A microelectronic module comprising:
a module substrate;
at least one flip-chip die attached to a top surface of the module substrate;
at least one heat spreader residing over and thermally coupled to the at least one flip-chip die;
a mold compound formed over the top surface of the module substrate and surrounding the at least one flip-chip die and the at least one heat spreader, wherein:
a top surface of the mold compound and a top surface of the at least one heat spreader are coplanar; and
a plurality of heat spreader notches is formed at the top surface of the at least one heat spreader;
a thermal interface material (TIM) section that fills each of the plurality of heat spreader notches and extends over the top surface of the at least one heat spreader and the top surface of the mold compound; and
a heat sink directly residing on the TIM section and thermally coupled to the at least one heat spreader through the TIM section, wherein the plurality of heat spreader notches is configured to constrain certain portions of the TIM section confined within the top surface of the at least one heat spreader.

14. The microelectronic module of claim 13 wherein the plurality of heat spreader notches includes one or more of discrete micro-holes, strip trenches, ring trenches, semi-ring trenches, and spiral trenches.

15. The microelectronic module of claim 14 wherein a cross-sectional view of each of the plurality of heat spreader notches is triangular, semicircular, or square.

16. The microelectronic module of claim 13 wherein:
at least one mold compound notch is formed at the top surface of the mold compound and surrounds the at least one heat spreader; and
the TIM section fills the at least one mold compound notch and each of the plurality of heat spreader notches and extends over the top surface of the at least one heat spreader and the top surface of the mold compound.

17. The microelectronic module of claim 16 wherein:
the plurality of heat spreader notches includes one or more of discrete micro-holes, strip trenches, ring trenches, semi-ring trenches, and spiral trenches; and
the at least one mold compound notch includes one or more of discrete micro-holes, strip trenches, ring trenches, semi-ring trenches, and spiral trenches.

18. The microelectronic module of claim 17 wherein:
a cross-sectional view of each of the plurality of heat spreader notches is triangular, semicircular, or square; and
a cross-sectional view of the at least one mold compound notch is triangular, semicircular, or square.

19. A microelectronic module comprising:
a module substrate;
at least one flip-chip die attached to a top surface of the module substrate;
at least one heat spreader residing over and thermally coupled to the at least one flip-chip die;
a mold compound formed over the top surface of the module substrate and surrounding the at least one flip-chip die and the at least one heat spreader, wherein:
a top surface of the mold compound and a top surface of the at least one heat spreader are coplanar; and
at least one mold compound notch is formed at the top surface of the mold compound and surrounding the at least one heat spreader;
a thermal interface material (TIM) section that fills the at least one mold compound notch and extends over the top surface of the at least one heat spreader and the top surface of the mold compound; and
a heat sink directly residing on the TIM section and thermally coupled to the at least one heat spreader through the TIM section, wherein the at least one mold compound notch is configured to constrain certain portions of the TIM section confined within the top surface of the at least one heat spreader.

20. A communication device comprising:
a control system;
a baseband processor;
receive circuitry; and
transmit circuitry, wherein at least one or any combination of the control system, the baseband processer, the transmit circuitry, and the receive circuitry is implemented in a microelectronic module, which has a module substrate, at least one flip-chip die, at least one heat spreader, a mold compound, at least one thermal interface material (TIM) section, at least one TIM barrier, and a heat sink, wherein:
the at least one flip-chip die is attached to a top surface of the module substrate, and the at least one heat spreader resides over and is thermally coupled to the at least one flip-chip die;
the mold compound is formed over the top surface of the module substrate and surrounds the at least one flip-chip die and the at least one heat spreader, wherein a top surface of the mold compound and a top surface of the at least one heat spreader are coplanar;
the at least one TIM barrier continuously surrounds a periphery of the at least one heat spreader and protrudes vertically beyond the top surface of the at least one heat spreader to provide at least one TIM cavity;
the at least one TIM section covers at least the top surface of the at least one heat spreader and fills the at least one TIM cavity; and
the heat sink resides over and is thermally coupled to the at least one heat spreader through the at least one TIM section, wherein the heat
sink is in contact with both the at least one TIM section and the at least one TIM barrier, and the TIM barrier is configured to prevent the at least one TIM section from shifting away from the top surface of the at least one heat spreader.

21. A method of fabricating a microelectronic package comprising:
providing a precursor module, which includes a module substrate, at least one flip-chip die, at least one heat spreader, and a mold compound, wherein:
the at least one flip-chip die is attached to a top surface of the module substrate, and the at least one heat spreader resides over and is thermally coupled to the at least one flip-chip die; and
the mold compound is formed over the top surface of the module substrate and surrounds the at least one flip-chip die and the at least one heat spreader, wherein a top surface of the mold compound and a top surface of the at least one heat spreader are coplanar;
forming at least one ring trench within the mold compound and continuously surrounding the at least one heat spreader, wherein the at least one ring trench extends vertically from the top surface of the mold compound and downwardly into the mold compound;
applying an adhesive material to fill the at least one ring trench and protrude the top surface of the at least one heat spreader, so as to form at least one thermal interface material (TIM) barrier continuously surrounding the at least one heat spreader, wherein the protrusion of the at least one TIM barrier provides at least one TIM cavity over the top surface of the at least one heat spreader;
applying a TIM over the top surface of the at least one heat spreader and fully filling the at least one TIM cavity to form at least one TIM section; and
placing a heat sink in contact with the at least one TIM section and the at least one TIM barrier, wherein the TIM barrier is configured to prevent the at least one TIM section from shifting away from the top surface of the at least one heat spreader, thereby maintaining thermal coupling between the heat sink and the at least one heat spreader through the at least one TIM section.
